(19) United States
(12) Patent Application Publication
(10) Pub. No.: US 2025/0173476 A1
(43) Pub. Date: May 29, 2025

(54) DIGITAL TWIN MANAGEMENT SYSTEM FOR INJECTION MOLDING EQUIPMENT

(71) Applicant: Yuilrobotics, co. Ltd., Incheon (KR)

(72) Inventors: Dong Heon KIM, Seoul (KR); Byoung Ju KIM, Seoul (KR); Min Guk PARK, Incheon (KR)

(73) Assignee: Yuilrobotics, co. Ltd., Incheon (KR)

(21) Appl. No.: 18/786,444

(22) Filed: Jul. 27, 2024

(30) Foreign Application Priority Data
Nov. 29, 2023 (KR) 10-2023-0168906

(51) Int. Cl. G06F 30/17

(52) U.S. Cl. CPC G06F 30/17

(57) ABSTRACT

The disclosure relates to a digital twin management system for injection molding equipment. A system synchronized with reality is provided by reflecting molding data acquired from a molding machine, a peripheral device, and a transfer device in a cyber physical model portion in real time based on extracted information, thereby facilitating management, increasing productivity, and reducing an operator's operation time.

### CROSS-REFERENCE TO RELATED APPLICATION(S)

This application claims priority from Korean Patent Application No. 10-2023-0168906, filed on Nov. 29, 2023, in the Korean Intellectual Property Office, the disclosure of which is incorporated herein by reference in its entirety.

### BACKGROUND

### 1. Field

The following description relates to a digital twin management system for injection molding equipment, and particularly, to a cyber physical system (CPS)-based digital twin management system technology.

### 2. Description of Related Art

Recently, the technology for improving productivity by applying the concept of a cyber physical system (CPS) to virtualize an actual system and performing modeling analysis has been proposed.

Meanwhile, injection molding is a widely used technology to manufacture gaskets, plastic products, and the like. An injection molding system is a system which includes a mold, a raw material supply device, and a peripheral device and uses a molten resin or the like to output a product with a desired form or shape.

Since injection molding is affected by various physical parameters related to a temperature, a speed, a pressure, and a time and even slight physical changes can cause defects, parameters should be precisely adjusted in real time. In particular, physical parameters of sealing products such as gaskets should be more precisely adjusted because a sealing effect may be fatally reduced by even slight shape errors.

Currently, these physical parameters are adjusted by operators visually checking defective products and based on their experience, and there is bound to be a difference in skill level between the operators. Thus, the quality of molded products is inconsistent, and it is difficult to fundamentally resolve defects.

Recently, attempts to automatically integrate and manage defects and minimize defect rates by introducing artificial intelligence (AI) technologies have been made in the injection molding field in line with the trend of the 4^{th} industrial revolution, but there is a need to develop a system that applies the concept of a CPS to model and visualize an actual injection molding system in real time to increase production efficiency and minimize defects.

Korean Patent No. 10-2379259 (“AIoT-based-integrated management system for injection manufacturing equipment and operation method thereof) discloses a technology for deriving optimal process conditions for injection manufacturing equipment based on injection molding condition data, injection peripheral device data, and mold internal data through an Al technology and supporting remote control appropriate for the process conditions, but does not apply a CPS technology, and furthermore, does not disclose a technology for fundamentally preventing defects in a cyber space by performing a predictive diagnosis on injection molding results for each process based on learned data.

### SUMMARY

This summary is provided to introduce a digital twin management system for injection molding equipment, which performs cyber modeling on injection molding equipment including a molding machine, a peripheral device, and a transfer device which interwork with each other in real time and performs analysis.

Additionally, this summary is provided to introduce a self-learning system which simulates the driving of injection molding equipment in a cyber space by learning a predictive diagnosis function using data accumulated by detecting a defect of an injection-molded product.

The following description relates to a digital twin management system for injection molding equipment, which is synchronized with reality by reflecting molding data (sensor data) acquired from a molding machine, a peripheral device, and a transfer device in a cyber physical model portion in real time based on extracted information.

The following description relates to a digital twin management system for injection molding equipment, in which sensor data related to a detected defect is accumulated and learned to perform predictive diagnosis on a defect of an injection-molded product.

### BRIEF DESCRIPTION OF THE DRAWINGS

FIG. 1 is a diagram illustrating a digital twin management system for injection molding equipment according to one embodiment.

FIG. 2 is a diagram illustrating a digital twin management system for injection molding equipment which has defect detecting and learning functions according to one embodiment.

FIG. 3 is a diagram illustrating a digital twin management system for injection molding equipment which has a predictive diagnosis function according to one embodiment.

FIG. 4 is a diagram for describing a process time and application parameters for each injection process according to one embodiment.

### DETAILED DESCRIPTION

The above-described and additional aspects are specified through embodiments described with reference to the accompanying drawings. It is understood that the components of each embodiment may be variously combined within the embodiment or with components of the other embodiment without other mentions or contradiction with each other. Terms used in the specification and claims should be interpreted as means and a concept consistent with a description or proposed technical spirit based on the principle that the inventor may appropriately define the concept of terms to describe the invention thereof in the best way. Hereinafter, exemplary embodiments of the disclosure will be described with reference to the accompanying drawings.

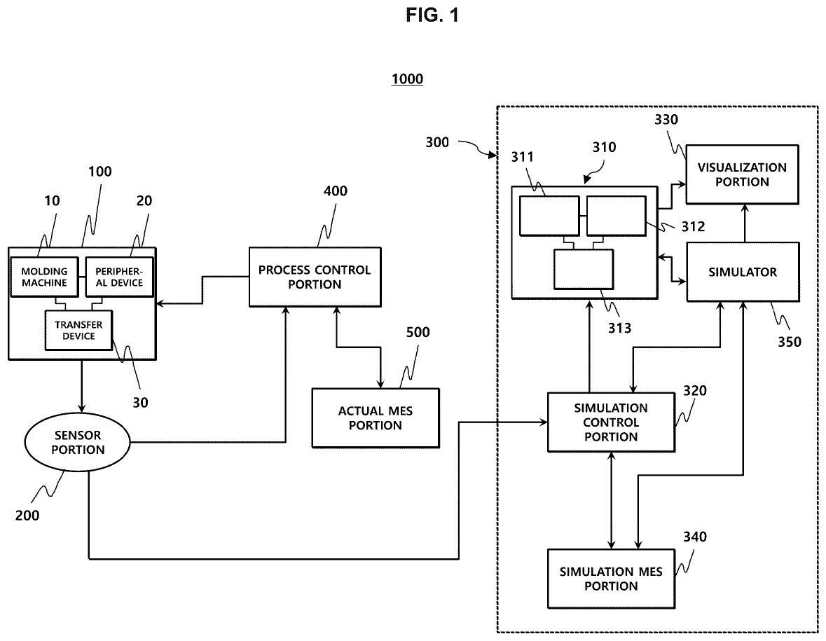

FIG. 1 is a diagram illustrating a digital twin management system for injection molding equipment according to one embodiment. As shown, a digital twin management system 1000 according to one embodiment may include a production equipment portion 100, a sensor portion 200, a cyber physical system portion 300, and a process control portion 400, and the cyber physical system portion 300 (dotted line area) may include a cyber physical model portion 310, a simulation control portion 320, and a visualization portion 330.

The production equipment portion 100 may include a molding machine 10, a peripheral device 20, and a transfer device 30. The molding machine 10 may form and output an injection-molded product. The peripheral device 20 may include a cooling device and an auto-feeding device. The transfer device 30 may transfer parts or materials required for molding or producing an injection-molded product.

According to one embodiment, the injection-molded product may be an insert injection-molded product. For example, the injection-molded product may be an injection-molded product of a fuel cell gasket including a frame and a gasket for a fuel cell which is double-injection-molded together with a plastic member, but is not limited thereto.

The fuel cell gasket may be a component included in a fuel cell. A metal separator referred to as a bipolar plate that constitutes a fuel cell serves as a current collector for transferring electrons generated at an anode to a cathode of a subsequent cell, serves to support a membrane electrode assembly (MEA) and provide a path for supplying a fuel and an oxidizer to the anode and cathode, respectively, and also serves as a path for removing water generated during the operation of a battery.

The fuel cell gasket may provide a sealing function such that a separator functions as the above path, and when there is a slight error in a shape of the fuel cell gasket, a fuel, an oxidizer, or water may leak out to cause fatal damage to the fuel cell. Therefore, the fuel cell gasket requires precise injection molding that does not allow any smallest error.

The molding machine 10 may include a mold, and the peripheral device 20 may perform a function of adjusting and setting physical molding environment conditions of the molding machine 10 or a function of supplying a molding raw material. For example, the peripheral device 20 may further include a chiller, a dehumidifier, a dryer, or a thermostat and may further include a barrel, an injection screw, or an injection portion which is adjacent to the mold and directly affects injection molding.

The transfer device 30 may be a device for transferring parts or materials required for molding or producing an injection-molded product and may be, for example, a robot or a conveyor. The robot may be provided as any robot such as a collaborative robot, a take-out robot, or a Cartesian robot.

The sensor portion 200 may be installed on or around the molding machine 10, the peripheral device 20, and the transfer device 30 and may detect a physical output of the molding machine 10, the peripheral device 20, and the transfer device 30 and may generate molding data. The physical output may include at least one of a speed, a time, a pressure, a weight, a temperature, and a displacement, and the molding data may be digital or analog data quantified based on a detected (sensed) physical output.

The sensor portion 200 may include a plurality of sensors that detect various physical indicators, such as a temperature sensor, a pressure sensor, a time sensor, a displacement sensor, and a speed sensor. The sensor portion 200 may include an Internet of Things (IoT) sensor.

The process control portion 400 may provide control data to the production equipment portion 100 to perform control such that physical parameters of the production equipment portion 100 are adjusted. The physical parameters of the production equipment portion 100 may include at least one of an injection amount, an injection time, a holding time, an injection speed, an injection pressure, a mold temperature, a cooling temperature, a cooling time, an inlet temperature of a cold runner block (CRB), and a vacuum degree.

As described above, the cyber physical system portion 300 may include the cyber physical model portion 310, the simulation control portion 320, the visualization portion 330, and a simulator 350.

The cyber physical model portion 310 may include a molding machine model 311 modeled to match the molding machine 10, a peripheral device model 312 modeled to match the peripheral device 20, and a transfer portion model 313 modeled to match the transfer device 30. Each model may have a modeling shape, which has the physical characteristics of the molding machine 10, the peripheral device 20, and the transfer device 30, implemented in a cyber space on a computer.

The simulation control portion 320 may receive molding data to generate data about the driving of the molding machine 10, the peripheral device 20, and the transfer device 30. The meaning of “driving” may include not only the movement of the molding machine 10, the peripheral device 20, and the transfer device 30, but also physical output information that may be expressed visually, such as a speed, a time, a pressure, or a temperature. Thus, the driving of the molding machine model 311, the peripheral device model 312, and the transfer portion model 313 may be synchronized with the driving of the molding machine 10, the peripheral device 20, and the transfer device 30.

The simulator 350 may calculate a simulation input value based on data about the driving of the molding machine, the peripheral device, and the transfer device and provide the simulation input value to the cyber physical model portion 310.

The visualization portion 330 may visualize the driving of the cyber physical model portion 310 reflected according to the simulation control portion 320. For example, the visualization portion 330 may display the molding machine model 311, the peripheral device model 312, and the transfer portion model 313 in a two-dimensional (2D) or three-dimensional (3D) manner, may display movement in real time, and may quantitatively display a driving state using numbers or colors.

The cyber physical model portion 310 and the visualization portion 330 may each be modeled and visualized by the simulator 350.

According to one embodiment, the digital twin management system 1000 may further include an actual manufacturing execution system (MES) portion 500 that provides driving information about an improvement in productivity of an injection-molded product and a reduction in defect rate to the process control portion 400 or the simulator 350. The actual MES portion 500 may include an application program. The actual MES portion 500 may interwork with the production equipment portion 100 through the process control portion 400.

According to one embodiment, the digital twin management system 1000 may further include a simulation MES portion 340 that provides driving information about an improvement in productivity of an injection-molded product and a reduction in defect rate to the simulation control portion 320 or the simulator 350. The simulation MES portion 340 may include an application program. The simulation MES portion 340 may include a function for a user interface (UI).

The simulation MES portion 340 may interwork with the cyber physical model portion 310 and the visualization portion 330 through the simulation control portion 320. The simulation MES portion 340 may be implemented to match the actual MES portion 500.

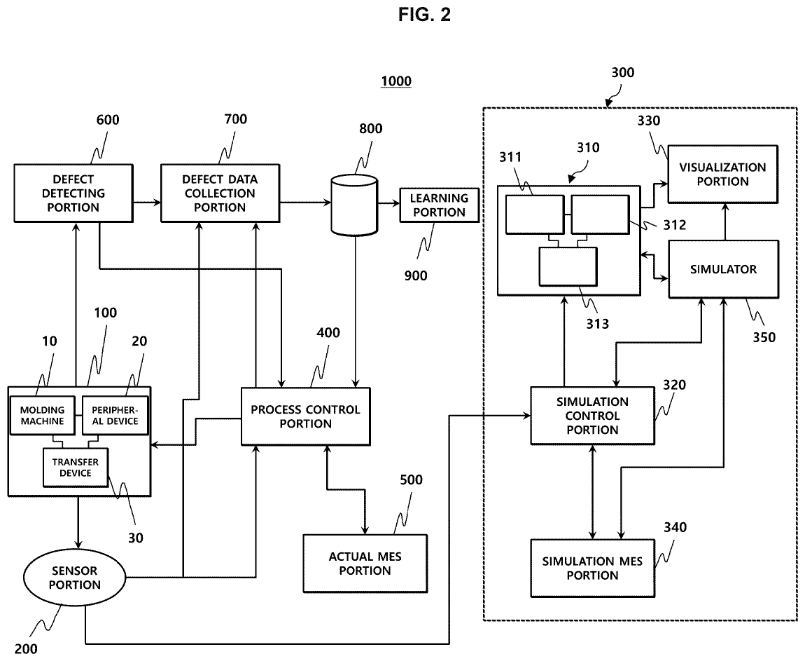

FIG. 2 is a diagram illustrating a digital twin management system for injection molding equipment, which has defect detecting and learning functions according to one embodiment.

A digital twin management system 1000 according to one embodiment may further include a defect detecting portion 600, a defect data collection portion 700, a learning database 800, and a learning portion 900.

The defect detecting portion 600 may detect a defect of an injection-molded product and generate defect data. The defect detecting portion 600 may detect or determine whether the injection-molded product is defective. A method by which the defect detecting portion 600 detects a defect of the injection-molded product may be diverse. For example, the defect may be detected by receiving images or image data of the injection-molded product from a camera using a camera portion (not shown).

The camera may be provided as a vision camera or a thermovision camera. When the camera is provided as the thermovision camera, temperatures of the injection-molded product and a mold may be photographed together, and a heat distribution image of the injection-molded product and a molding machine (mold) may be generated.

Assuming that the injection-molded product includes a gasket, examples of the above defect include various cases such as a case in which the gasket is disconnected (cut) due to non-filling, a case in which a portion of the gasket is torn due to impurities in the mold, a case in which air bubbles are present in the gasket, and a case in which burs are present in the gasket.

The defect data collection portion 700 may receive defect data, molding data, and control data and may generate and store learning data based on molding data that contributes to the generation of defect data for each defect type. Learning data related to collected defect data may be used to update a predictive diagnosis portion 950 in the future.

The molding data that contributes to the generation of the defect data may be molding data corresponding to the formation of a defect of an injection-molded product produced in a process operation performed at a time point before an injection-molded product detected to be defective is produced. The learning data may be classified for each process or each defect type. The learning database 800 may receive learning data related to a defect from the defect data collection portion 700 to constitute and store big data.

The learning portion 900 may receive the learning data related to the defect from the defect data collection portion 700 or the learning database 800 and may learn the learning data to generate updated physical parameters of a production equipment portion.

The defect data collection portion 700, the learning database 800, or the learning portion 900 may be electrically connected to a process control portion 400 or the predictive diagnosis portion 950, but otherwise, data may be simply transferred offline by an operator.

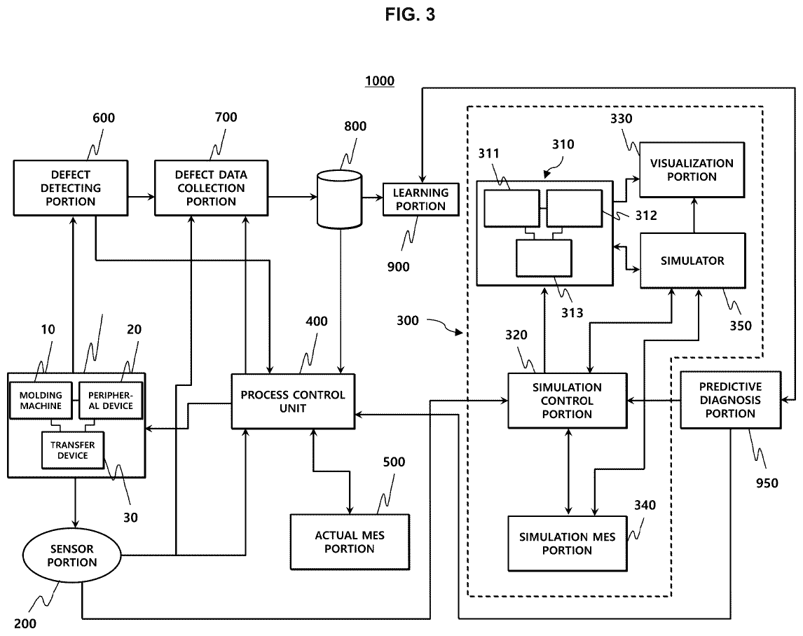

FIG. 3 is a diagram illustrating a digital twin management system for injection molding equipment, which has a predictive diagnosis function according to an embodiment. As shown, a predictive diagnosis portion 950 may generate predictive diagnosis data for predicting the occurrence of a defect in an injection-molded product based on the learning data. Molding data, defect data, and control data may be labeled. The learning data may be based on the molding data, the defect data, and the control data.

The predictive diagnosis data may be used in a process control portion 400 and/or a simulation control portion 320 in the future. The predictive diagnosis portion 950 may be provided to include an artificial intelligence (Al) engine.

The meaning of “predicting the occurrence of the defect in the injection-molded product” may mean that a diagnosis is performed in advance to predict whether a defect of an injection-molded product occurs when an injection process is performed under current molding conditions.

According to one embodiment, the predictive diagnosis portion 950 may provide predictive diagnosis data to the process control portion 400 so that the process control portion 400 readjusts physical parameters of a production equipment portion 100.

According to one embodiment, the predictive diagnosis portion 950 may provide the predictive diagnosis data to the simulation control portion 320 so that a cyber physical model portion 310 is updated. Thus, it is possible to visually simulate the occurrence of an actual defect.

The predictive diagnosis portion 950 may include hardware or software. For example, the predictive diagnosis portion 950 may include a cloud server, hardware, or an edge box to which an Al technology is applied.

According to one embodiment, the predictive diagnosis portion 950 may provide predictive diagnosis data related to the occurrence or type of a defect to a learning portion, and a learning portion 900 may calculate an updated Al engine parameter set in which the sum of differences between predictive diagnosis data and learning data is minimized. The predictive diagnosis portion 950 may update the predictive diagnosis data based on the updated Al engine parameter set.

According to one embodiment, the predictive diagnosis portion 950 may provide the predictive diagnosis data to the process control portion 400 before a defect of an injection-molded product occurs, thereby allowing the process control portion 400 to change physical parameters of a molding machine. The process control portion 400 may adjust physical parameters of a production equipment portion 100 based on the provided predictive diagnosis data to prevent a defect from occurring in an injection-molded product.

In addition, before a defect of an injection-molded product occur, the predictive diagnosis portion 950 may provide predictive diagnosis data to the simulation control portion 320 so that the cyber physical model portion 310 is updated, thereby visually simulating the occurrence of an actual defect in a cyber space.

According to one embodiment, a time point at which the predictive diagnosis portion 950 provides the predictive diagnosis data to the simulation control portion 320 may be earlier than a time point at which the predictive diagnosis portion 950 provides the predictive diagnosis data to the process control portion 400. In this way, by first providing the predictive diagnosis data to the simulation control portion 320, the safety of a system can be guaranteed.

The predictive diagnosis portion 950 may generate optimal predictive diagnosis data using an Al algorithm such as a recurrent neural network (RNN), a convolutional neural network (CNN), multi-layer perceptron (MLP), or random forest.

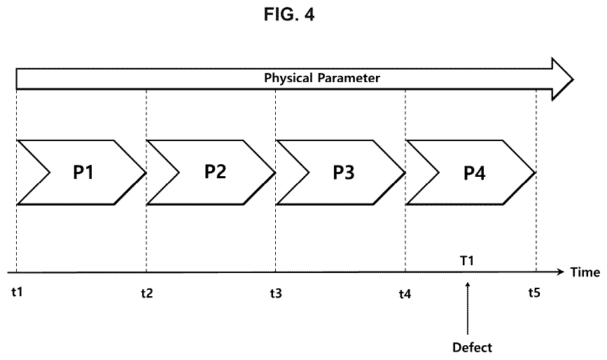

FIG. 4 is a diagram for describing a process time and application parameters for each injection process according to one embodiment.

As shown, an injection process is divided into operations P1, P2, P3, and P4, and physical parameters of specific production equipment may be applied for each operation. For example, when a defect in an injection-molded product occurs at a time point T1 in process operation P4, learning data may be generated based on physical parameters and molding data (sensor data) of a molding machine applied between a time t4 and the time point T1, and the learning data may be learned to generate predictive diagnosis data. A section or range of time applied to collect learning data may be appropriately adjusted and set.

In this way, when a defect is detected, in consideration of a time required for each process of an injection process, data that contributes to the occurrence of a defect among stored data is classified for each defect type and learned, thereby fundamentally preventing defects.

According to the proposed invention, data of injection molding equipment is reflected in a digital twin in real time through a sensor portion, thereby facilitating management, increasing productivity, and reducing an operator's operation time.

Additionally, according to the proposed invention, the occurrence of a defect of an injection-molded product can be minimized, and production yield can be increased.

The effects of the disclosure are not limited to the above-describe effects, and other effects that are not described above will be apparent to a person having ordinary skill in the art from the specification and the accompanying drawings.

While the disclosure has been described above with respect to embodiments in conjunction with the accompanying drawings, the disclosure is not limited thereto and should be interpreted to cover various modifications that will be apparent to those of ordinary skill in the art. The claims are intended to cover such modifications.

Although all of the components of the embodiments of the disclosure may have been described as being assembled or operatively connected as one component, the disclosure is not necessarily limited to the embodiments. That is, within the objective scope of the disclosure, the respective components may be selectively and operatively combined as one or more components.

What is claimed is:

1. A digital twin management system for injection molding equipment, comprising:
a production equipment portion including a molding machine configured to form and output an injection-molded product, a peripheral device including a cooling device and an auto-feeding device, and a transfer device configured to transfer a part or a material;
a sensor portion installed on the molding machine, the peripheral device, and the transfer device to detect a physical output of the molding machine, the peripheral device, and the transfer device and generate molding data;
a process control portion configured to provide control data to the production equipment portion to perform control such that physical parameters of the production equipment portion are adjusted; and
a cyber physical system portion, wherein the cyber physical system portion includes:
a cyber physical model portion including a molding machine model modeled to match the molding machine, a peripheral device model modeled to match the peripheral device portion, and a transfer portion model modeled to match the transfer device;

20. a simulation control portion configured to receive the molding data and generate data about driving of the molding machine, the peripheral device, and the transfer device;
a simulator configured to calculate a simulation input value based on the data about the driving of the molding machine, the peripheral device, and the transfer device and provide the calculated simulation input value to the cyber physical model portion; and
a visualization portion configured to visualize driving of the cyber physical model portion.

2. The digital twin management system of claim 1, further comprising a simulation manufacturing execution system (MES) portion configured to provide driving information about an improvement in productivity of the injection-molded product and a reduction in defect rate to the simulation control portion or the simulator.

3. The digital twin management system of claim 1, further comprising a defect detecting portion configured to detect a defect of the injection-molded product and generate defect data.

4. The digital twin management system of claim 3, further comprising:
a defect data collection portion configured to receive the defect data, the molding data, and the control data and generate and store learning data based on the molding data that contribute to generation of the defect data for each defect type; and
a learning portion configured to receive the learning data from the defect data collection portion and learn the learning data to generate updated physical parameters of the production equipment portion.

5. The digital twin management system of claim 4, further comprising a predictive diagnosis portion configured to generate predictive diagnosis data for predicting occurrence of a defect of the injection-molded product based on the learning data.

6. The digital twin management system of claim 5, wherein the predictive diagnosis portion provides the predictive diagnosis data to the process control portion so that the process control portion readjusts the physical parameters of the production equipment portion.

7. The digital twin management system of claim 6, wherein the predictive diagnosis portion provides the predictive diagnosis data to the simulation control portion so that the cyber physical model portion is updated.

8. The digital twin management system of claim 7, wherein a time point at which the predictive diagnosis portion provides the predictive diagnosis data to the simulation control portion is earlier than a time point at which the predictive diagnosis portion provides the predictive diagnosis data to the process control portion.
